(19) United States
(12) Patent Application Publication
(10) Pub. No.: US 2019/0296701 A1
(43) Pub. Date: Sep. 26, 2019

(54) HIGH FREQUENCY CIRCUIT AND HIGH FREQUENCY POWER AMPLIFIER

(71) Applicant: MITSUBISHI ELECTRIC CORPORATION, Tokyo (JP)

(72) Inventors: Takaaki YOSHIOKA, Tokyo (JP); Masatake HANGAI, Tokyo (JP); Koji YAMANAKA, Tokyo (JP)

(73) Assignee: MITSUBISHI ELECTRIC CORPORATION, Tokyo (JP)

(21) Appl. No.: 16/348,818

(22) PCT Filed: Dec. 19, 2016
(86) PCT No.: PCT/JP2016/087778

§ 371 Date: May 9, 2019

(51) Int. Cl. H03F 1/56; H03H 7/38; H03F 3/213

(52) U.S. Cl. CPC H03F 1/565; H03H 7/38; H03F 2200/387; H03F 2200/222; H03F 3/213

(57) ABSTRACT

A wire (14) having a first end connected to a line (2) and a second end connected to a second end of a resistor (9) and having an inductive component La resonating with a parasitic capacitance Ca of the resistor (9), or a wire (16) having a first end connected to a line (3) and a second end connected to a second end of a resistor (12) and having an inductive component Lb resonating with a parasitic capacitance Cb of the resistor (12) are provided. Consequently, gain flatness in an operating frequency band can be improved.

### TECHNICAL FIELD

The present invention relates to a high frequency circuit for transmitting a high frequency signal and a high frequency power amplifier on which the high frequency circuit is mounted.

### BACKGROUND ART

For example, in a high frequency power amplifier for amplifying a high frequency signal such as a microwave, a millimeter wave, or the like, it is required that deviation of a gain within an operating frequency band is small, and stability outside the operating frequency band is obtained, that is, unnecessary oscillation does not occur from a low range to a high range outside the operating frequency band.

In the high frequency power amplifier, generally, an input matching circuit that is a high frequency circuit is provided in a preceding stage of a transistor that is an amplifying element.

In an input matching circuit provided in a high frequency power amplifier disclosed in Patent Literature 1 below, a resistor is shunt-connected to a main line, and an open stub is connected to the resistor.

The length of the open stub included in the input matching circuit is a quarter wavelength at a frequency outside an operating frequency band of the high frequency power amplifier, that is, a frequency of one-half of an operating frequency of the high frequency power amplifier.

For this reason, at the frequency of one-half of the operating frequency, the resistor included in the input matching circuit is equivalent to a resistor having a second end grounded. Thus, in the high frequency power amplifier, the resistor functions to suppress the gain, so that the high frequency power amplifier can be stabilized.

At the operating frequency of the high frequency power amplifier, the length of the open stub is a length of one-half wavelength.

For this reason, at the operating frequency of the high frequency power amplifier, the resistor included in the input matching circuit is equivalent to a resistor having a second end being opened. Thus, in the high frequency power amplifier, the resistor included in the input matching circuit can be neglected, so that most of the gain is not lost.

As a result, in the high frequency power amplifier, unnecessary oscillation at the frequency of one-half of the operating frequency can be suppressed while suppressing a change in the gain at the operating frequency.

### CITATION LIST

### Patent Literatures

Patent Literature 1: JP 2001-144560 A

### SUMMARY OF INVENTION

### Technical Problem

Since the conventional high frequency power amplifier is configured as described above, if the resistor included in the input matching circuit is an ideal resistor, the gain in the operating frequency band becomes substantially constant. However, since the resistor included in the input matching circuit is not actually an ideal resistor but has a parasitic capacitance, deviation occurs between a gain at a lower limit frequency and a gain at an upper limit frequency in the operating frequency band. For this reason, there has been a problem that gain flatness of the high frequency power amplifier is lost.

The present invention has been made to solve the problem described above, and it is an object to obtain a high frequency circuit and a high frequency power amplifier which can improve the gain flatness in the operating frequency band.

### Solution to Problem

A high frequency circuit according to the present invention includes: a series line in which a first line and a second line are connected together via a first resistor; a second resistor having a first end grounded; and a first wire having a first end connected to the first line or the second line, having a second end connected to a second end of the second resistor, and having an inductive component resonating with a parasitic capacitance of the second resistor.

### Advantageous Effects of Invention

According to the present invention, a first wire is provided to have a first end connected to the first line or the second line, have a second end connected to a second end of the second resistor, and have an inductive component resonating with a parasitic capacitance of the second resistor, so that there is an effect that the gain flatness can be improved in the operating frequency band.

### BRIEF DESCRIPTION OF DRAWINGS

FIG. 1 is a configuration diagram illustrating a high frequency circuit according to a first embodiment of the present invention;

FIG. 2 is a configuration diagram illustrating a high frequency circuit in which shunt resistors are directly connected to lines 2 and 3, respectively;

FIG. 3 is a circuit diagram illustrating an equivalent circuit of the high frequency circuit of FIG. 2 in a case where resistors 9 and 12 that are shunt resistors are ideal resistors;

FIG. 4 is an explanatory diagram illustrating an example of frequency characteristics of an attenuation amount in the high frequency circuit of FIG. 2 in the case where the resistors 9 and 12 are ideal resistors;

FIG. 5 is a circuit diagram illustrating an equivalent circuit of the high frequency circuit of FIG. 2 in a case where the resistors 9 and 12 respectively have parasitic capacitances;

FIG. 6 is an explanatory diagram illustrating an example of frequency characteristics of the attenuation amount in the high frequency circuit of FIG. 2 in the case where the resistors 9 and 12 respectively have parasitic capacitances;

FIG. 7 is a circuit diagram illustrating an equivalent circuit of the high frequency circuit according to the first embodiment of the present invention;

FIG. 8 is an explanatory diagram illustrating an example of the frequency characteristics of the attenuation amount in the high frequency circuit according to the first embodiment of the present invention;

FIG. 9 is a configuration diagram illustrating a high frequency circuit in which the resistor 9 is connected to the line 2 by wires 14;

FIG. 10 is a configuration diagram illustrating a high frequency circuit in which the resistor 12 is connected to the line 3 by wires 16;

FIG. 11 is a configuration diagram illustrating a high frequency circuit in which a wire 21 is loaded;

FIG. 12 is a circuit diagram illustrating an equivalent circuit of the high frequency circuit in which the wire 21 is loaded;

FIG. 13 is an explanatory diagram illustrating an example of the frequency characteristics of the attenuation amount in the high frequency circuit in which the wire 21 is loaded;

FIG. 14 is a configuration diagram illustrating a high frequency circuit according to a second embodiment of the present invention;

FIG. 15 is a circuit diagram illustrating an equivalent circuit of the high frequency circuit according to the second embodiment of the present invention;

FIG. 16 is an explanatory diagram illustrating an example of the frequency characteristics of the attenuation amount in the high frequency circuit according to the second embodiment of the present invention;

FIG. 17 is a configuration diagram illustrating a high frequency circuit according to a third embodiment of the present invention;

FIG. 18 is a configuration diagram illustrating another high frequency circuit according to the third embodiment of the present invention;

FIG. 19 is a configuration diagram illustrating a high frequency power amplifier according to a fourth embodiment of the present invention; and

FIG. 20 is a configuration diagram illustrating a high frequency power amplifier according to a fifth embodiment of the present invention.

### DESCRIPTION OF EMBODIMENTS

Hereinafter, to explain the present invention in more detail, some embodiments for carrying out the present invention will be described with reference to the accompanying drawings.

### First Embodiment

FIG. 1 is a configuration diagram illustrating a high frequency circuit according to a first embodiment of the present invention.

In FIG. 1, a circuit board 1 is a dielectric substrate such as an alumina substrate, a high dielectric constant substrate, or the like.

A main line of the high frequency circuit is a series line 20 in which a line 2 and a line 3 are connected together via a first resistor 4.

The line 2 is a first line formed on the front surface of the circuit board 1 with a metal pattern, for example. In addition, a first end of the line 2 is connected to an external circuit on the input side (not illustrated) by a wire, a gold ribbon, or the like.

The line 3 is a second line formed on the front surface of the circuit board 1 with a metal pattern, for example. In addition, a first end of the line 3 is connected to an external circuit on the output side (not illustrated) by a wire, a gold ribbon, or the like.

The first resistor 4 is a circuit in which a resistor 6a, a metal pattern 5, and a resistor 6b are connected together in series.

The metal pattern 5 is formed on the front surface of the circuit board 1.

The resistor 6a is a resistance member connected between the line 2 and the metal pattern 5, and has a resistive component R1 and a parasitic capacitance C1.

The resistor 6b is a resistance member connected between the metal pattern 5 and the line 3, and has a resistive component R2 and a parasitic capacitance C2.

A metal pattern 7 is formed on the front surface of the circuit board 1.

A via hole 8 has a first end connected to the metal pattern 7, and a second end connected to the ground formed on the back surface of the circuit board 1.

A resistor 9 is a second resistor having a first end connected to the metal pattern 7, and a short point is formed at the first end of the resistor 9. That is, the first end of the resistor 9 is grounded.

The resistor 9 has a resistive component Ra and a parasitic capacitance Ca, and the parasitic capacitance Ca of the resistor 9 is larger than each of the parasitic capacitances C1 and C2 of the resistors 6a and 6b.

Here, the short point is formed at the first end of the resistor 9 using the via hole 8, but the short point may be formed at the first end of the resistor 9 without using the via hole 8.

A metal pattern 10 is formed on the front surface of the circuit board 1.

A via hole 11 has a first end connected to the metal pattern 10, and a second end connected to the ground formed on the back surface of the circuit board 1.

A resistor 12 is a third resistor having a first end connected to the metal pattern 10, and a short point is formed at the first end of the resistor 12. That is, the first end of the resistor 12 is grounded.

The resistor 12 has a resistive component Rb and a parasitic capacitance Cb, and the parasitic capacitance Cb of the resistor 12 is larger than each of the parasitic capacitances C1 and C2 of the resistors 6a and 6b.

Here, the short point is formed at the first end of the resistor 12 using the via hole 11, but the short point may be formed at the first end of the resistor 12 without using the via hole 11.

A metal pattern 13 is formed in the vicinity of the line 2 on the front surface of the circuit board 1, and has a first end connected to a second end of the resistor 9.

Wires 14 are first wires each having a first end connected to the line 2 and a second end connected to a second end of the metal pattern 13.

The wires 14 each has an inductive component La resonating with the parasitic capacitance Ca of the resistor 9.

A metal pattern 15 is formed in the vicinity of the line 3 on the front surface of the circuit board 1, and has a first end connected to a second end of the resistor 12.

Wires 16 are second wires each having a first end connected to the line 3 and a second end connected to a second end of the metal pattern 15.

The wires 16 each has an inductive component Lb resonating with the parasitic capacitance Cb of the resistor 12.

In the first embodiment, an example is described in which the resistor 9 is shunt-connected to the line 2 using the wires 14 that are the first wires, and the resistor 12 is shunt-connected to the line 3 using the wires 16 that are the second wires. However, this is merely an example, and the resistor 9 may be shunt-connected to the line 3 using the wires 14 that are the first wires, and the resistor 12 may be shunt-connected to the line 2 using the wires 16 that are the second wires.

Next, the operation will be described.

A principle of an attenuator function of the high frequency circuit of the first embodiment will be described in which the attenuation amount is uniform within an operating frequency band of an amplifier connected to the line 2 or the line 3, and changes steeply at a desired frequency other than the operating frequency band.

To explain frequency characteristics of the attenuation amount in the high frequency circuit of the first embodiment, an example of a high frequency circuit will be described in which the resistor 9 that is a shunt resistor is directly connected to the line 2, and the resistor 12 that is a shunt resistor is directly connected to the line 3.

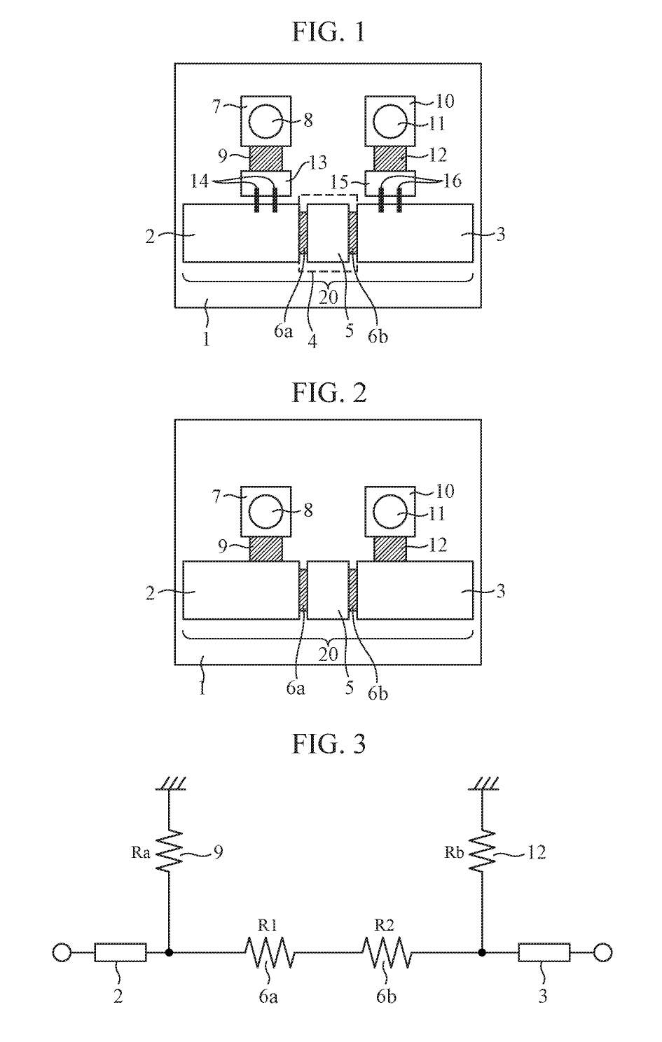

FIG. 2 is a configuration diagram illustrating the high frequency circuit in which the shunt resistors are directly connected to the lines 2 and 3, respectively. In FIG. 2, the same reference numerals as those in FIG. 1 denote the same or corresponding portions.

FIG. 3 is a circuit diagram illustrating an equivalent circuit of the high frequency circuit of FIG. 2 in a case where the resistors 9 and 12 that are shunt resistors are ideal resistors.

In the case where the resistors 9 and 12 are ideal resistors, the high frequency circuit of FIG. 2 is an ideal n type attenuator.

In a case where the high frequency circuit of FIG. 2 is the ideal n type attenuator, the attenuation amount becomes constant regardless of the frequency.

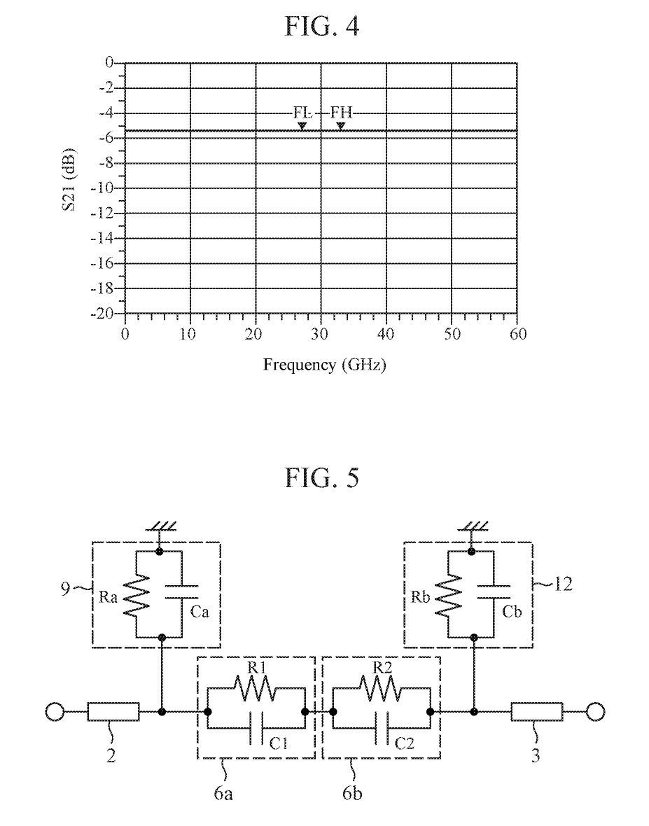

FIG. 4 is an explanatory diagram illustrating an example of the frequency characteristics of the attenuation amount in the high frequency circuit of FIG. 2 in the case where the resistors 9 and 12 are ideal resistors.

In FIG. 4, the horizontal axis represents a frequency (GHz) and the vertical axis represents an attenuation amount S21 (dB). The operating frequency band is FL to FH, FL is a low range of the operating frequency band, and FH is a high range of the operating frequency band.

In the example of FIG. 4, the attenuation amount S21 (dB) is constant at 5.5 dB regardless of the frequency.

In the high frequency circuit of FIG. 2, in the case where the resistors 9 and 12 are ideal resistors, as is apparent from FIG. 4, the attenuation amount is constant regardless of the frequency.

In practice, however, the resistor 9 has a small amount of parasitic capacitance Ca and a small amount of parasitic inductance as parasitic components, and the resistor 12 has a small amount of parasitic capacitance Cb and a small amount of parasitic inductance as parasitic components.

Influence of the parasitic components of the resistors 9 and 12 increases as the frequency becomes higher, so that the resistors 9 and 12 cannot be regarded as pure resistors.

Since the resistive components Ra and Rb of the resistors 9 and 12 mounted in the high frequency circuit have significant sizes, influence of the parasitic capacitances Ca and Cb appears large among the parasitic components. For this reason, here, an equivalent circuit is considered in which the parasitic capacitances Ca and Cb are loaded in parallel with the resistive components Ra and Rb.

FIG. 5 is a circuit diagram illustrating the equivalent circuit of the high frequency circuit illustrated in FIG. 2 in a case where the resistors 9 and 12 respectively have parasitic capacitances Ca and Cb.

In FIG. 5, C1 is the parasitic capacitance of the resistor 6a, and C2 is the parasitic capacitance of the resistor 6b.

The attenuation amount of the high frequency circuit is influenced by the parasitic capacitances C1 and C2 of the resistors 6a and 6b connected in series to the lines 2 and 3 that are the main lines.

The parasitic capacitances C1 and C2 of the resistors 6a and 6b act so that the attenuation amount increases in the low range (FL) of the operating frequency band and the attenuation amount decreases in the high range (FH) of the operating frequency band.

The attenuation amount of the high frequency circuit is also influenced by the parasitic capacitances Ca and Cb of the resistors 9 and 12 shunt-connected to the lines 2 and 3 that are main lines.

The parasitic capacitances Ca and Cb of the resistors 9 and 12 act so that the attenuation amount decreases in the low range (FL) of the operating frequency band and the attenuation amount increases in the high range (FH) of the operating frequency band.

Thus, in a case where the resistors 6a, 6b, 9, and 12 are designed so that each of the parasitic capacitances Ca and Cb of the resistors 9 and 12 is larger than each of the parasitic capacitances C1 and C2 of the resistors 6a and 6b, the attenuation amount of the high frequency circuit decreases in the low range (FL) of the operating frequency band and increases in the high range (FH) of the operating frequency band.

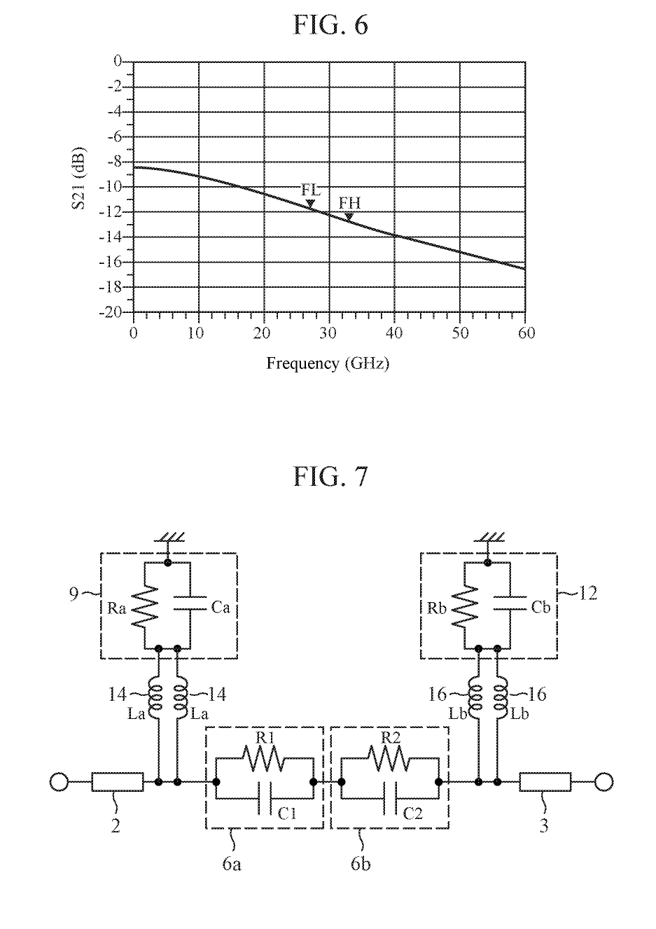

FIG. 6 is an explanatory diagram illustrating an example of the frequency characteristics of the attenuation amount in the high frequency circuit of FIG. 2 in the case where the resistors 9 and 12 respectively have the parasitic capacitances Ca and Cb.

In FIG. 6, the horizontal axis represents a frequency (GHz) and the vertical axis represents an attenuation amount S21 (dB).

In the example of FIG. 6, the attenuation amount S21 (dB) is 11.7 dB at 27 GHz that is a low range (FL) of the operating frequency band, and the attenuation amount S21 (dB) is 12.7 dB at 33 GHz that is a high range (FH) of the operating frequency band. Namely, the attenuation amount is larger by 1 dB in the high range (FH) than in the low range (FL) of the operating frequency band.

In the high frequency circuit of the first embodiment, to make the attenuation amount in the low range (FL) of the operating frequency band equal to the attenuation amount in the high range (FH) of the operating frequency band, the resistor 9 is shunt-connected to the line 2 that is the main line by connecting the line 2 and the metal pattern 13 together by the wires 14, as illustrated in FIG. 1.

In addition, in the high frequency circuit of the first embodiment, the resistor 12 is shunt-connected to the line 3 that is the main line by connecting the line 3 and the metal pattern 15 together by the wires 16, as illustrated in FIG. 1.

FIG. 7 is a circuit diagram illustrating an equivalent circuit of the high frequency circuit according to the first embodiment of the present invention. In FIG. 7, the same reference numerals as those in FIG. 1 denote the same or corresponding portions.

Since FIG. 1 illustrates an example in which the numbers of the wires 14 and 16 are each two, FIG. 7 also illustrates an example in which the numbers of the wires 14 and 16 are each two.

By connecting the line 2 and the metal pattern 13 via wires 14, the inductive components La of the wires 14 resonate with the parasitic capacitance Ca of the resistor 9.

In addition, by connecting the line 3 and the metal pattern 15 via the wires 16, the inductive components Lb of the wires 16 resonate with the parasitic capacitance Cb of the resistor 12.

For this reason, at resonance frequencies of the inductive components La and Lb of the wires 14 and 16 and the parasitic capacitances Ca and Cb of the resistors 9 and 12, the attenuation amount steeply increases as compared with the attenuation amount in the operating frequency band. In addition, also at frequencies in the vicinity of the resonance frequencies, the attenuation amount is larger than the attenuation amount in the operating frequency band.

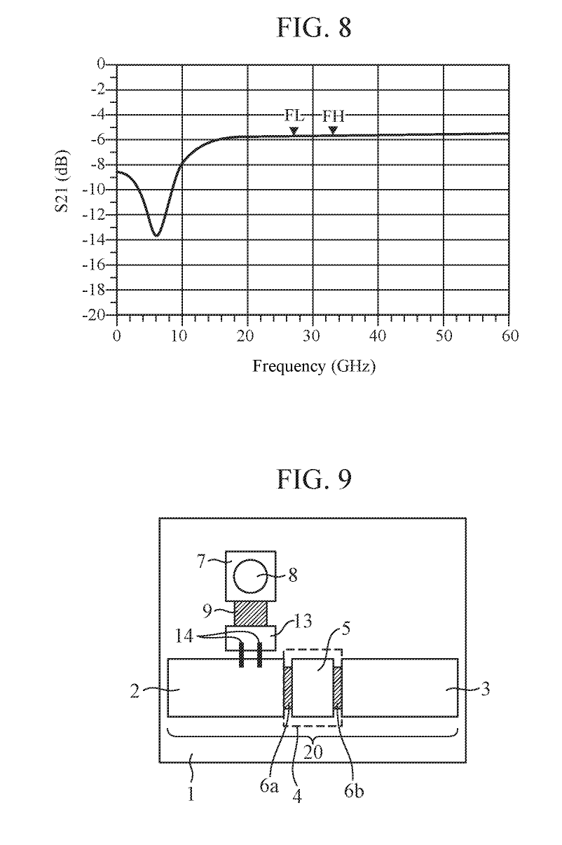

FIG. 8 is an explanatory diagram illustrating an example of the frequency characteristics of the attenuation amount in the high frequency circuit according to the first embodiment of the present invention.

FIG. 8 illustrates an example in which the inductive components La of the wires 14 and the parasitic capacitance Ca of the resistor 9 resonate with each other at 7 GHz, and the inductive components Lb of the wires 16 and the parasitic capacitance Cb of the resistor 12 resonate with each other at 7 GHz.

As a result, the attenuation amount of the high frequency circuit steeply increases at 7 GHz that is the resonance frequency. In addition, also at 0 to 14 GHz that are frequencies in the vicinity of the resonance frequency, the attenuation amount is larger than that at greater than or equal to about 14 GHz.

As a result, in the example of FIG. 8, the attenuation amount due to the resonance is offset with the attenuation amount caused by the parasitic capacitances Ca and Cb, so that the attenuation amount is substantially constant in the frequency range of FL to FH that is the operating frequency band.

That is, the attenuation amount at 27 GHz that is the low range (FL) of the operating frequency band and the attenuation amount at 33 GHz that is the high range (FH) of the operating frequency band are both about 5.6 dB, and the attenuation amount is substantially constant within the operating frequency band.

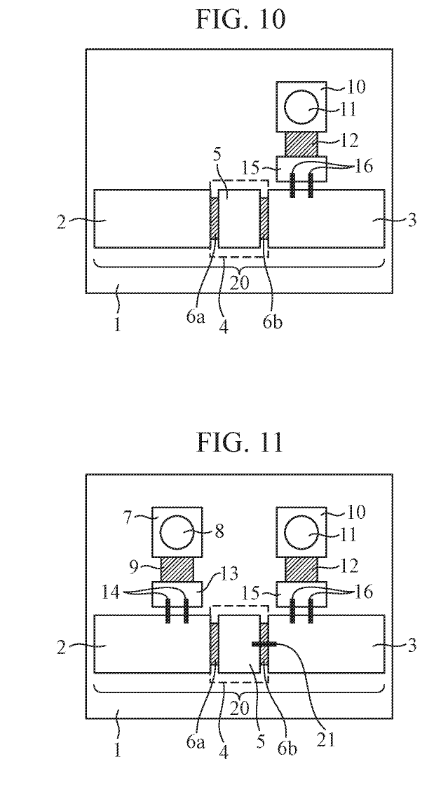

In the first embodiment, an example is described in which the resistor 9 is connected to the line 2 by the wires 14, and the resistor 12 is connected to the line 3 by the wires 16; however, only the resistor 9 may be connected to the line 2 by the wires 14 as illustrated in FIG. 9. In addition, only the resistor 12 may be connected to the line 3 by the wires 16 as illustrated in FIG. 10.

FIG. 9 is a configuration diagram illustrating a high frequency circuit in which the resistor 9 is connected to the line 2 by the wires 14, and FIG. 10 is a configuration diagram illustrating a high frequency circuit in which the resistor 12 is connected to the line 3 by the wires 16.

In the high frequency circuit of FIG. 1, it is described that the resistor 12 is the third resistor and the wires 16 are the second wires; however, in the high frequency circuit of FIG. 10, the resistor 12 is the second resistor and the wires 16 are the first wires.

In a case where only the resistor 9 is connected to the line 2 by the wires 14 or only the resistor 12 is connected to the line 3 by the wires 16, reflection characteristics may be degraded as compared with a case where both the resistor 9 and the resistor 12 are connected to the lines 2 and 3 by the wires 14 and 16, respectively. However, in the case where only the resistor 9 is connected to the line 2 by the wires 14 or only the resistor 12 is connected to the line 3 by the wires 16, the attenuation amount within the operating frequency band can be made substantially constant similarly to the case where both the resistor 9 and the resistor 12 are connected to the lines 2 and 3.

In addition, in the case where only the resistor 9 is connected to the line 2 by the wires 14 or only the resistor 12 is connected to the line 3 by the wires 16, a circuit area can be reduced as compared with the case where both the resistor 9 and the resistor 12 are connected to the lines 2 and 3.

As is apparent from the above description, according to the first embodiment, the high frequency circuit includes the wires 14 each having the first end connected to the line 2 and the second end connected to the second end of the resistor 9 and having the inductive component La resonating with the parasitic capacitance Ca of the resistor 9, or the wires 16 each having the first end connected to the line 3 and the second end connected to the second end of the resistor 12 and having the inductive component Lb resonating with the parasitic capacitance Cb of the resistor 12. Consequently, there is an effect that gain flatness in the operating frequency band can be improved.

That is, according to the first embodiment, the attenuator function in which the attenuation amount is uniform within the operating frequency band of the amplifier connected to the high frequency circuit, and the attenuation amount changes steeply at a desired frequency other than the operating frequency band can be implemented.

### Second Embodiment

In the first embodiment, the high frequency circuit is described in which the metal pattern 5 and the line 3 are connected together via the resistor 6b.

In this second embodiment, a high frequency circuit will be described in which the metal pattern 5 and the line 3 are connected together via the resistor 6b, and the metal pattern 5 and the line 3 are also connected together via a wire 21.

FIG. 11 is a configuration diagram illustrating a high frequency circuit in which the wire 21 is loaded, and in FIG. 11, since the same reference numerals as those in FIG. 1 denote the same or corresponding portions, the description thereof will be omitted.

The wire 21 is a third wire having a first end connected to the metal pattern 5 and a second end connected to the line 3.

The wire 21 has an inductive component Lc.

In the example shown in FIG. 11, the number of wires 21 is one. However, the number of wires 21 may be two or more.

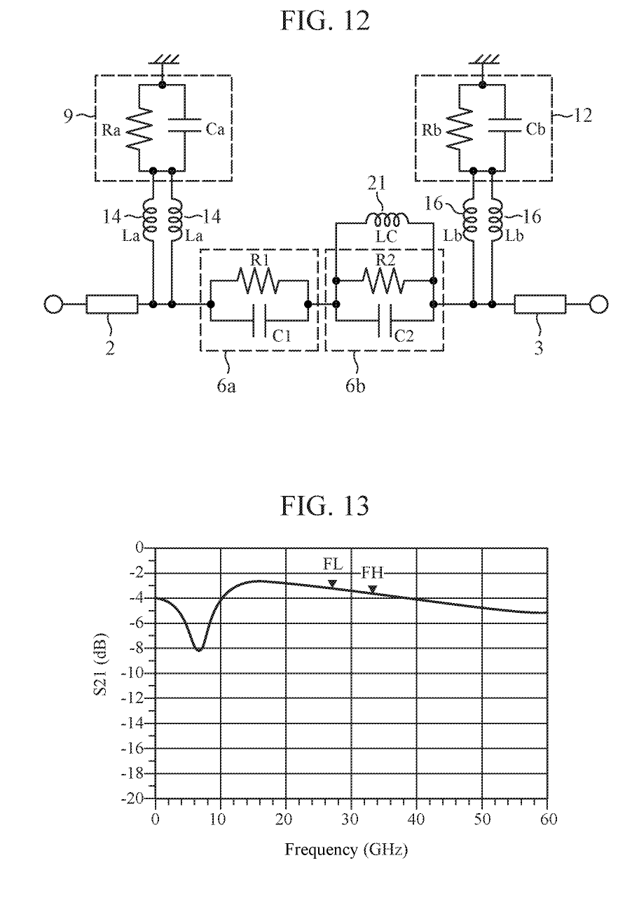

FIG. 12 is a circuit diagram illustrating an equivalent circuit of the high frequency circuit in which the wire 21 is loaded. In FIG. 12, the same reference numerals as those in FIG. 11 denote the same or corresponding portions.

FIG. 13 is an explanatory diagram illustrating an example of the frequency characteristics of the attenuation amount in the high frequency circuit in which the wire 21 is loaded.

Next, the operation will be described.

In the high frequency circuit of FIG. 11, the metal pattern 5 and the line 3 are connected together via the wire 21, and the resistor 6b is short-cut by the wire 21, so that the attenuation amount of the entire high frequency circuit decreases.

In addition, since the wire 21 has the inductive component Lc, the attenuation amount of the high frequency circuit has characteristics depending on the frequency, and the attenuation amount decreases in the low range (FL) of the operating frequency band and increases in the high range (FH) of the operating frequency band.

In the example of FIG. 13, the attenuation amount is 3.1 dB at 27 GHz that is the low range (FL) of the operating frequency band, and is 3.5 dB at 33 GHz that is the high range (FH) of the operating frequency band.

In the example of FIG. 13, the attenuation amount of the entire high frequency circuit is smaller than that of the first embodiment; however, deviation of 0.4 dB appears between the attenuation amount at 27 GHz that is a low range (FL) of the operating frequency band and the attenuation amount at 33 GHz that is a high range (FH) of the operating frequency band.

In the second embodiment, to eliminate the deviation of 0.4 dB between the attenuation amount at 27 GHz that is a low range (FL) of the operating frequency band and the attenuation amount at 33 GHz that is a high range (FH) of the operating frequency band, the numbers of the wires 14 and 16 are each changed from two to one.

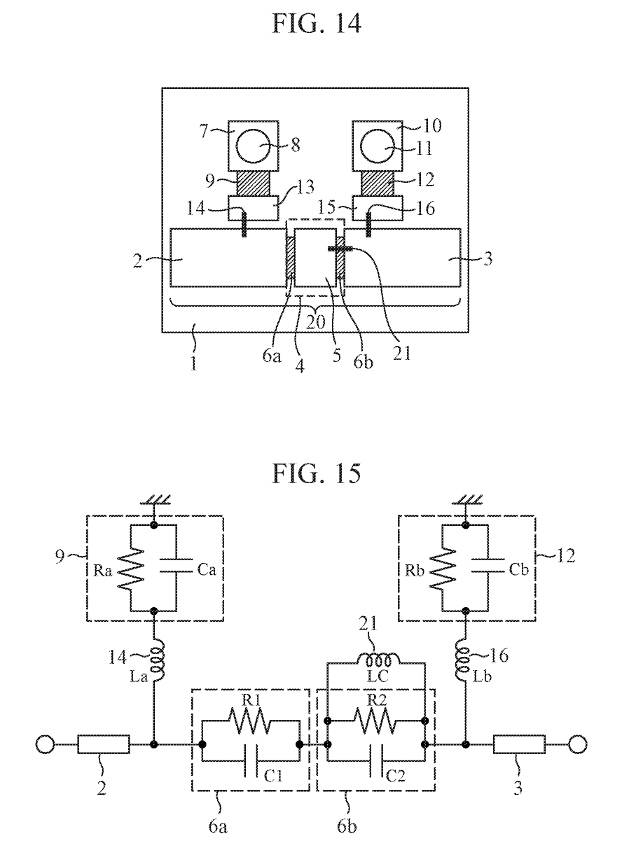

FIG. 14 is a configuration diagram illustrating the high frequency circuit according to the second embodiment of the present invention, and FIG. 15 is a circuit diagram illustrating an equivalent circuit of the high frequency circuit according to the second embodiment of the present invention. FIGS. 14 and 15 each illustrates an example in which the numbers of the wires 14 and 16 are each one.

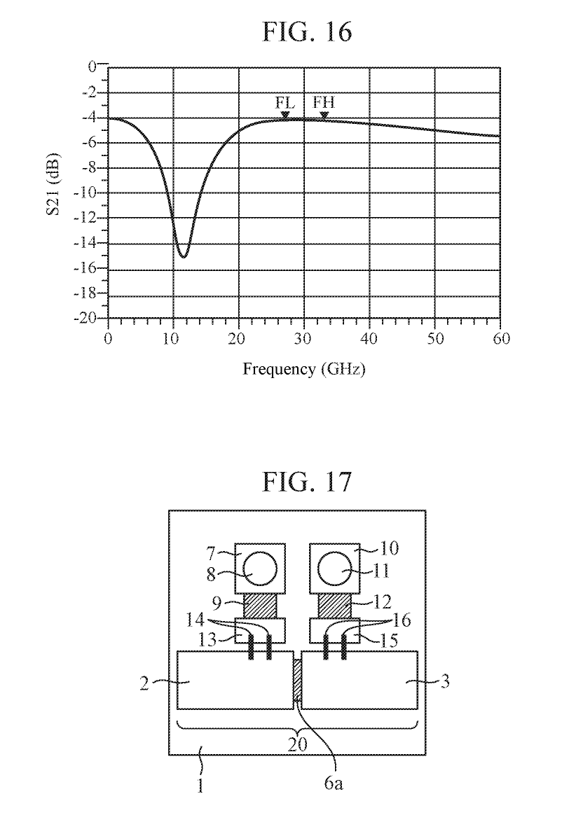

FIG. 16 is an explanatory diagram illustrating an example of the frequency characteristics of the attenuation amount in the high frequency circuit according to the second embodiment of the present invention.

By changing the numbers of the wires 14 and 16 each from two to one, total amounts of the inductive components La and Lb of the wires 14 and 16 change, so that an increase of the attenuation amount in the low range (FL) of the operating frequency band becomes larger than an increase of the attenuation amount in the high range (FH) of the operating frequency band.

That is, the increase of the attenuation amount in the low range (FL) of the operating frequency band becomes larger than the increase of the attenuation amount in the high range (FH) of the operating frequency band, so that the deviation of the attenuation amount due to loading of the wire 21 is eliminated, and gain flatness in the operating frequency band can be improved.

In the example of FIG. 16, the attenuation amount is 4.1 dB at 27 GHz that is the low range (FL) of the operating frequency band, 4.2 dB at 33 GHz that is the high range (FH) of the operating frequency band, and the attenuation amount is substantially constant within the operating frequency band.

Here, an example is described in which the attenuation amount is substantially constant within the operating frequency band by changing the numbers of the wires 14 and 16 each from two to one; however, depending on values of respective circuit elements in the high frequency circuit, the attenuation amount may be substantially constant within the operating frequency band by changing the numbers of the wires 14 and 16 each to three or more.

The numbers of the wires 14 and 16 can be changed not only before production of the high frequency circuit that is the circuit board, but also after the production of the high frequency circuit.

In addition, here, the example is described in which the numbers of the wires 14 and 16 are changed; however, the attenuation amount may be made substantially constant within the operating frequency band by changing the lengths of the wires 14 and 16.

As is apparent from the above description, according to the second embodiment, the metal pattern 5 and the line 3 are connected together via the resistor 6b, and the metal pattern 5 and the line 3 are also connected together via the wire 21. Consequently, there is an effect that the attenuation amount of the entire high frequency circuit can be reduced as compared with that of the first embodiment.

In addition, by changing the numbers or lengths of the wires 14 and 16, the gain flatness can be improved within the operating frequency band by adjustment of the deviation of the attenuation amount even after the production of the high frequency circuit that is the circuit board.

In the second embodiment, an example is described in which the first end of the wire 21 is connected to the metal pattern 5, and the second end of the wire 21 is connected to the line 3; however, the first end of the wire 21 may be connected to the line 2, and the second end of the wire 21 may be connected to the metal pattern 5.

### Third Embodiment

In the first embodiment, an example is described in which the first resistor 4 is a circuit where the resistor 6a, the metal pattern 5, and the resistor 6b are connected together in series; however, a circuit configuration of the first resistor 4 is not limited thereto.

In this third embodiment, an example of another circuit configuration of the first resistor 4 will be described.

FIG. 17 is a configuration diagram illustrating a high frequency circuit according to the third embodiment of the present invention. In FIG. 17, since the same reference numerals as those in FIG. 1 denote the same or corresponding portions, the description thereof will be omitted.

In the example of FIG. 17, the first resistor 4 includes only the resistor 6a, and the line 2 and the line 3 are connected together via the resistor 6a.

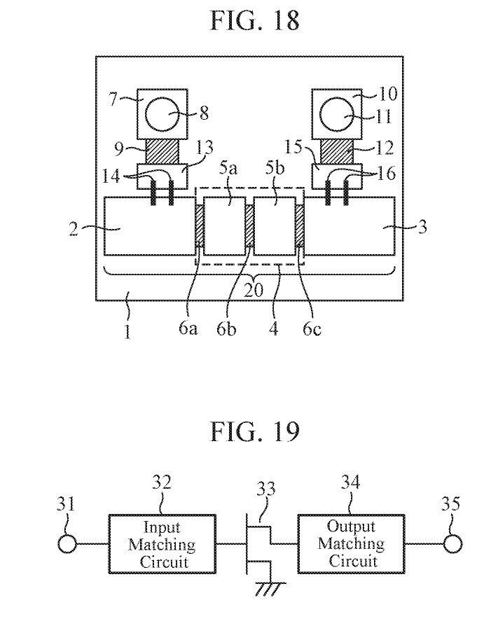

FIG. 18 is a configuration diagram illustrating another high frequency circuit according to the third embodiment of the present invention. In FIG. 18, since the same reference numerals as those in FIG. 1 denote the same or corresponding portions, the description thereof will be omitted.

In the example of FIG. 18, the number of resistors included in the first resistor 4 is three, namely, resistors 6a, 6b, and 6c, and the first resistor 4 is a circuit in which the resistor 6a, a metal pattern 5a, the resistor 6b, a metal pattern 5b, and the resistor 6c are connected together in series.

FIG. 18 illustrates the example in which the number of resistors included in the first resistor 4 is three; however, the number of resistors included in the first resistor 4 may be four or more.

By increasing the number of resistors included in the first resistor 4, the attenuation amount can be increased. In addition, by decreasing the number of resistors included in the first resistor 4, the attenuation amount can be decreased.

The attenuation amount can be finely set by appropriate changing a combination of resistors to be short-cut by the wire 21 as illustrated in FIGS. 11 and 14, out of the one or more resistors included in the first resistor 4.

### Fourth Embodiment

In this fourth embodiment, an example will be described in which any of the high frequency circuits in the first to third embodiments is used in a matching circuit included in a high frequency power amplifier.

FIG. 19 is a configuration diagram illustrating the high frequency power amplifier according to the fourth embodiment of the present invention.

In FIG. 19, an input terminal 31 is a terminal for inputting a high frequency signal from the outside.

An input matching circuit 32 is a circuit for impedance matching between an external circuit (not illustrated) connected to the input terminal 31 and a transistor 33.

The transistor 33 is an amplifying element for amplifying power of a high frequency signal input from the input terminal 31.

An output matching circuit 34 is a circuit for impedance matching between the transistor 33 and an external circuit (not illustrated) connected to an output terminal 35.

The output terminal 35 is a terminal for outputting the high frequency signal whose power is amplified by the transistor 33 to the outside.

At least one matching circuit out of the input matching circuit 32 and the output matching circuit 34 includes a high frequency circuit according to any of the first to third embodiments.

In the high frequency power amplifier, by providing the input matching circuit 32, the impedance matching is performed on the input side of the transistor 33, and by providing the output matching circuit 34, the impedance matching is performed on the output side of the transistor 33.

In the high frequency power amplifier, at least one matching circuit includes a high frequency circuit according to any of the first to third embodiments, so that an attenuator function in which the attenuation amount is uniform within an operating frequency band of the transistor 33, and steeply changes at a desired frequency other than the operating frequency can be implemented.

As a result, a high frequency power amplifier having high gain flatness in the operating frequency band while suppressing unnecessary oscillation can be obtained.

### Fifth Embodiment

In the fourth embodiment, a high frequency power amplifier on which one transistor 33 is mounted is described. In this fifth embodiment, a high frequency power amplifier on which a plurality of transistors 33 is mounted will be described.

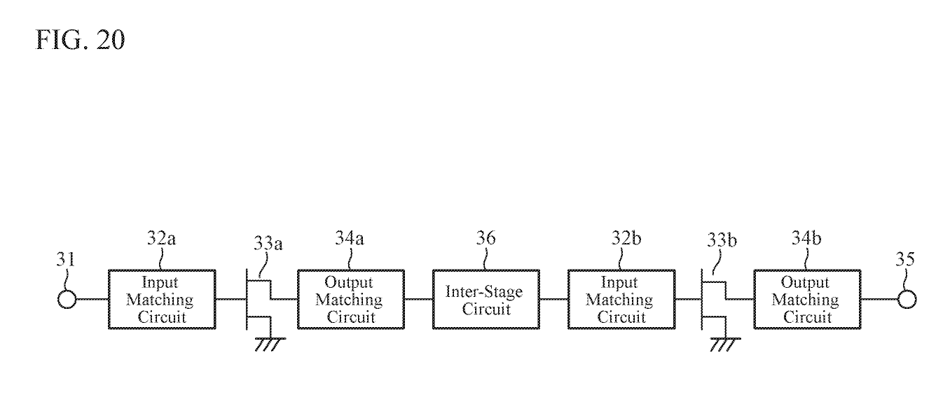

FIG. 20 is a configuration diagram illustrating the high frequency power amplifier according to the fifth embodiment of the present invention. In FIG. 20, since the same reference numerals as those in FIG. 19 denote the same or corresponding portions, the description thereof will be omitted.

An input matching circuit 32a is a circuit for impedance matching between an external circuit (not illustrated) connected to an input terminal 31a and a transistor 33a.

The transistor 33a is an amplifying element for amplifying power of a high frequency signal input from the input terminal 31a.

An output matching circuit 34a is a circuit for impedance matching on the output side of the transistor 33a.

An input matching circuit 32b is a circuit for impedance matching on the input side of a transistor 33b.

The transistor 33b is an amplifying element for amplifying the power of the high frequency signal passed through the input matching circuit 32b.

An output matching circuit 34b is a circuit for impedance matching between the transistor 33b and an external circuit (not illustrated) connected to the output terminal 35.

An inter-stage circuit 36 is a circuit for coupling the output matching circuit 34a and the input matching circuit 32b.

FIG. 20 illustrates an example in which the high frequency power amplifier mounts two transistors 33a and 33b; however, three or more transistors may be mounted.

At least one circuit out of the input matching circuits 32a, 32b, the output matching circuits 34a, 34b, and the inter-stage circuit 36 includes a high frequency circuit according to any of the first to third embodiments.

In the high frequency power amplifier, by providing the input matching circuits 32a and 32b, the impedance matching is performed on the input sides of the transistors 33a and 33b, and by providing the output matching circuits 34a and 34b, the impedance matching is performed on the output sides of the transistors 33a and 33b.

In the high frequency power amplifier, at least one of the input matching circuits 32a, 32b, the output matching circuits 34a, 34b, and the inter-stage circuit 36 includes a high frequency circuit according to any of the first to third embodiments, so that an attenuator function in which the attenuation amount is uniform within an operating frequency band of the transistors 33a and 33b, and steeply changes at a desired frequency other than the operating frequency can be implemented.

As a result, a high frequency power amplifier having high gain flatness in the operating frequency band while suppressing unnecessary oscillation can be obtained.

Note that, in the invention of the present application, within the scope of the invention, free combination of any embodiments, a modification of any component of each embodiment, or omission of any component in each embodiment is possible.

### INDUSTRIAL APPLICABILITY

The present invention is suitable for a high frequency circuit for transmitting a high frequency signal, and is also suitable for a high frequency power amplifier on which the high frequency circuit is mounted.

### REFERENCE SIGNS LIST

1 Circuit board
2 Line (first line)
3 Line (second line)
4 First resistor
5, 5a, 5b Metal pattern
6a, 6b, 6c Resistor (resistance member)
7 Metal pattern
8 Via hole
9 Resistor (second resistor)
10 Metal pattern
11 Via hole
12 Resistor (third resistor)
13 Metal pattern
14 Wire (first wire)
15 Metal pattern
16 Wire (second wire)
20 Series line
21 Wire (third wire)
31 Input terminal
32, 32a, 32b Input matching circuit
33, 33a, 33b Transistor
34, 34a, 34b Output matching circuit
35 Output terminal
36 Inter-stage circuit

1. A high frequency circuit comprising:
a series line in which a first line and a second line are connected together via a first resistor;
a second resistor having a first end grounded; and
a first wire having a first end connected to the first line or the second line, having a second end connected to a second end of the second resistor, and having an inductive component resonating with a parasitic capacitance of the second resistor.

2. The high frequency circuit according to claim 1, wherein the parasitic capacitance of the second resistor is larger than a parasitic capacitance of the first resistor.

3. The high frequency circuit according to claim 1, further comprising:
a third resistor having a first end grounded; and
a second wire having a first end connected to the second line and a second end connected to a second end of the third resistor in a case where the first end of the first wire is connected to the first line, the second wire having the first end connected to the first line and the second end connected to the second end of the third resistor in a case where the first end of the first wire is connected to the second line, the second wire having an inductive component resonating with a parasitic capacitance of the third resistor.

4. The high frequency circuit according to claim 3, wherein the parasitic capacitance of each of the second and third resistors is larger than a parasitic capacitance of the first resistor.

5. The high frequency circuit according to claim 1, wherein the first resistor is a circuit in which a plurality of resistance members is connected together in series via a metal pattern.

6. The high frequency circuit according to claim 5, further comprising a third wire having a first end connected to the metal pattern included in the first resistor and a second end connected to the second line.

7. The high frequency circuit according to claim 5, further comprising a third wire having a first end connected to the first line and a second end connected to the metal pattern included in the first resistor.

8. A high frequency power amplifier comprising
an input matching circuit, a transistor, and an output matching circuit connected together in series, wherein
at least one matching circuit out of the input matching circuit or the output matching circuit includes a high frequency circuit including:
a series line in which a first line and a second line are connected together via a first resistor;
a second resistor having a first end grounded; and
a first wire having a first end connected to the first line or the second line, having a second end connected to a second end of the second resistor, and having an inductive component resonating with a parasitic capacitance of the second resistor.

9. The high frequency power amplifier according to claim 8, wherein
the high frequency circuit includes:
a third resistor having a first end grounded; and
a second wire having a first end connected to the second line and a second end connected to a second end of the third resistor in a case where the first end of the first wire is connected to the first line, the second wire having the first end connected to the first line and the second end connected to the second end of the third resistor in a case where the first end of the first wire is connected to the second line, the second wire having an inductive component resonating with a parasitic capacitance of the third resistor.

10. A high frequency power amplifier comprising
a plurality of circuits connected together in series via an inter-stage circuit, the plurality of circuits each including an input matching circuit, a transistor, and an output matching circuit connected together in series, wherein
at least one circuit out of the input matching circuit, the output matching circuit, and the inter-stage circuit includes a high frequency circuit including:
a series line in which a first line and a second line are connected together via a first resistor;
a second resistor having a first end grounded; and
a first wire having a first end connected to the first line or the second line, having a second end connected to a second end of the second resistor, and having an inductive component resonating with a parasitic capacitance of the second resistor.

11. The high frequency power amplifier according to claim 10, wherein
the high frequency circuit includes:
a third resistor having a first end grounded; and
a second wire having a first end connected to the second line and a second end connected to a second end of the third resistor in a case where the first end of the first wire is connected to the first line, the second wire having the first end connected to the first line and the second end connected to the second end of the third resistor in a case where the first end of the first wire is connected to the second line, the second wire having an inductive component resonating with a parasitic capacitance of the third resistor.
